(19) United States
(12) Patent Application Publication
(10) Pub. No.: US 2009/0022198 A1
(43) Pub. Date: Jan. 22, 2009

(54) PACKAGE STRUCTURE OF COMPOUND SEMICONDUCTOR DEVICE AND FABRICATING METHOD THEREOF

(75) Inventors: PIN CHUAN CHEN, HSINCHU COUNTY (TW); CHAO HSIUNG CHANG, TAIPEI COUNTY (TW); SHEN BO LIN, HSINCHU CITY (TW); LUNG HSIN CHEN, HSINCHU COUNTY (TW); WEN LIANG TSENG, HSINCHU CITY (TW)

Correspondence Address: WPAT, PC;INTELLECTUAL PROPERTY ATTORNEYS, 2030 MAIN STREET, SUITE 1300, IRVINE, CA, 92614, US

(73) Assignee: ADVANCED OPTOELECTRONIC TECHNOLOGY INC., HSINCHU COUNTY (TW)

(21) Appl. No.: 12/173,763

(22) Filed: Jul. 15, 2008

(30) Foreign Application Priority Data
Jul. 19, 2007 (TW) 096126300

(51) Int. Cl. H01S 5/028; H01L 33/00; H01L 31/18; H01L 31/0232

(52) U.S. Cl. 372/49.01; 257/98; 257/432; 438/27; 438/65

(57) ABSTRACT

A package structure of a compound semiconductor device comprises a thin conductive film with a pattern, a die, at least one metal wire or metal bump and a transparent encapsulation material. The die is mounted on the first surface of the thin conductive film, and is electrically connected to the thin conductive film through the metal wire or the metal bump. The transparent encapsulation material is overlaid on the first surface of the conductive film and the die. A second surface of the conductive film is not covered by the transparent encapsulation material, and is opposite the first surface.

### BACKGROUND OF THE INVENTION

(A) Field of the Invention

The present invention relates to a package structure of a compound semiconductor device and fabricating method thereof, and more particularly, to a thin package structure and fabricating method of a photoelectric semiconductor device.

(B) Description of the Related Art

Because the light emitting diode (LED) pertaining to the photoelectric device has advantages of a small body, high efficiency and long lifetime, it is deemed as an excellent illuminant source for the next generation. Furthermore, LCD (liquid crystal display) technology is developing rapidly and full color is the current trend in electronic product displays. Therefore, the white series LEDs are not only applicable to indication lights and large size display screens but also to most consumer electronic products such as mobile phones and personal digital assistants (PDA).

FIG. 1 is a schematic cross sectional diagram of the conventional SMD (surface mount device) of an LED device. An LED die 12 is mounted on an N type conductive copper foil 13b covering an insulation layer 13c through die bonding paste 11, and is electrically connected to a P type conductive copper foil 13a and the N type conductive copper foil 13b through metal wires 15. The assembly of the P type conductive copper foil 13a, N type conductive copper foil 13b and insulation layer 13c is on a substrate 13. Furthermore, a transparent encapsulation material 14 covers the substrate 13, metal wires 15 and die 12 so that the whole LED device 10 can be protected against damage from environmental and external forces.

The LED device 10 utilizes a common printed circuit board (PCB) as the substrate 13. The total thickness of the LED device 10 is limited by the insulation layer 13c of the substrate 13, hence it cannot be reduced further. However, the trend of consumer electronic products is towards a light, thin, short and small body in recent years. Accordingly, each of the internal devices of the consumer electronic product and its shell needs to be miniaturized. On the other hand, the insulation layer 13c is made mostly of epoxy resin with poor heat dissipation, and therefore is not suitable for a high power chemical compound semiconductor as a heat-transferring path.

In view of the above, the consumer electronic products market is in urgent need of a photoelectric compound semiconductor device with a thin type package. The device not only needs to have a reduced thickness for saving space, but also needs to address the heat dissipation problem. With such a device, reliable, high power electronics products will be more easily manufactured.

### SUMMARY OF THE INVENTION

One aspect of the present invention provides the package structure of a compound semiconductor device and fabricating method thereof. The semiconductor device has external electrodes or contacts uncovered by an encapsulation material. There is no printed circuit board between a die and external electrodes for transmitting electrical signals, so the heat dissipation of the device is improved.

Another aspect of the present invention provides the package structure of very thin semiconductor device and fabricating method thereof. The thickness of the device can be reduced for saving space because of the use of a thin substrate.

According the aforesaid aspects, the present invention discloses the package structure of a compound semiconductor device comprising a conductive film with a pattern, a die and a transparent encapsulation material. The die is mounted on a first surface of the conductive film. The encapsulation material is overlaid on the first surface of the conductive film and die. A second surface of the conductive film is not covered by the encapsulation material, wherein the second surface is opposite to the first surface.

The die is electrically connected to the conductive film through at least one metallic wire, or is electrically connected to the conductive film through a plurality of bumps.

The second surface of the conductive film is uncovered by encapsulation material. The material of the conductive film is silver, nickel, copper, tin, aluminum or the alloy of the aforesaid metals. Indium tin oxide (ITO), indium zinc oxide (IZO), indium gallium oxide (IGO) and indium tungsten oxide (IWO) also are suitable for the material of the conductive film.

The conductive film comprises an N type electrode and a P type electrode.

The transparent encapsulation material is further mixed with fluorescent powders.

The die is mounted on the first surface of the conductive film through die bonding paste or eutectic bonding.

The present invention discloses the package method of a compound semiconductor device comprising the steps of: providing a temporary substrate; forming a conductive film with a pattern on the temporary substrate, wherein the conductive film has a first surface and a second surface opposite the first surface; mounting a die to the first surface of the conductive film; overlaying a transparent encapsulation material on the first surface of the conductive film and the die; and removing the temporary substrate.

The present invention further comprises a step of electrically connecting the die to the conductive film through a plurality of metallic wires.

Alternatively, the present invention also discloses a step of electrically connecting the die to the conductive film through a plurality of bumps.

The conductive film is formed on the temporary substrate through printing, screen printing, electroforming, chemical plating or sputtering.

The temporary substrate is removed by bending, separating, etching, laser cutting or grinding.

The present invention discloses the package structure of a compound semiconductor device comprising a thin film substrate with a pattern, a die and a transparent encapsulation material. The thin film substrate comprises an upper conductive film, an insulation film including a plurality of openings, and a lower conductive film, wherein the insulation film is sandwiched between the upper conductive film and lower conductive film. The die is mounted on the upper conductive film. The encapsulation material is overlaid on the upper conductive film and the die.

Each of the upper conductive film and lower conductive film comprises an N type electrode and a P type electrode. The N type electrodes of the upper conductive film and lower conductive film contact each other through the plurality of openings, and the P type electrodes of the upper conductive film and lower conductive film also contact each other through the plurality of openings.

The thickness of the insulation layer is preferably between 0.01 mm and 0.1 mm. The material of the insulation layer is polyimide, PV (polyvinyl), PC (polycarbonate), PVC (polyvinyl chloride), PMMA (polymethylmethacrylate) or acrylic.

The present invention discloses the package method of a compound semiconductor device comprising the steps of: providing an insulation film including a plurality of openings; forming an upper conductive film and a lower conductive film respectively on two surfaces of the insulation film, wherein the upper conductive film and the lower conductive film contact each other through the plurality of openings; mounting a die on the upper conductive film; and overlaying a transparent encapsulation material on the upper conductive film and the die.

The present invention further comprises two steps of forming the insulation film on a plate and forming the plurality of openings on the insulation film.

The insulation film is formed on the plate through dispensation, dip or sol gel.

The plurality of openings are formed on the insulation film through mechanical drilling, laser drilling or plasma etching.

The upper conductive film and the lower conductive film are formed on the insulation film through electroplating, printing or copper foil pressing.

The present invention further discloses the package structure of a compound semiconductor device comprising a thin substrate having a first electrode and a second electrode, a chemical compound semiconductor die on the thin substrate; means for mounting the semiconductor die on the thin substrate; and a transparent encapsulation material overlaying the semiconductor die.

The semiconductor die is a light emitting diode die, a laser diode die or a photo sensor die.

The means comprise wire bonding and flip chip bonding for mounting the semiconductor die on the thin substrate. The die is mounted on the thin substrate through die bonding paste or eutectic bonding before the wire bonding.

The package structure further comprises a color conversion material mixed with the transparent encapsulation material, and the color conversion material is fluorescent powder. The transparent encapsulation material is epoxy resin or silicone.

The package structure further comprises a reflective layer around the transparent encapsulation material.

The present invention discloses the package method of a compound semiconductor device comprising the steps of: providing a thin film substrate having a first electrode and a second electrode; mounting a semiconductor die on the thin film substrate whereby a positive electrode of the semiconductor die is connected to a first electrode and a negative electrode of the semiconductor die is connected to the second electrode; and overlaying a transparent encapsulation material on the semiconductor die.

The thin film substrate with a pattern is a patterning conductive layer formed on a temporary substrate. The temporary substrate is removed after the semiconductor die is covered with the transparent encapsulation material.

The conductive film is formed on the temporary substrate through printing, screen printing, electroforming, chemical plating or sputtering. The temporary substrate is removed by bending, separating, etching, laser cutting or grinding.

The conductive film substrate comprises a first conductive layer with a pattern, an insulation film with a plurality of holes and a second conductive layer with a pattern.

The manufacturing method of the conductive film substrate comprises the steps of: providing an insulation film having a plurality of holes; fixing the first conductive layer with a first pattern and the second conductive layer respectively with a second pattern on two opposite surfaces of the insulation film with a plurality of holes whereby the first conductive layer with a pattern and the second conductive layer with a pattern are electrically connected to each other through the plurality of holes.

### BRIEF DESCRIPTION OF THE DRAWINGS

The objectives and advantages of the present invention will become apparent upon reading the following description and upon reference to the accompanying drawings in which:

FIG. 1 is a schematic cross sectional diagram of the conventional SMD (surface mount device) of an LED device;

FIGS. 2A-2F are schematic illustrations showing the manufacturing steps of the package structure of a compound semiconductor device in accordance with the present invention;

FIGS. 3A-3B are cross-sectional and top views of the package structure of a compound semiconductor device in accordance with another embodiment of the present invention;

FIG. 4 is an exploded diagram showing each layer of a thin film substrate in accordance with the present invention;

FIG. 5 is a cross-sectional diagram of a thin film substrate in accordance with the present invention;

FIGS. 6A-6B are cross-sectional diagrams of the package structures of compound semiconductor devices in accordance with two further embodiments of the present invention; and

FIG. 7 is a top view of the package structure of a compound semiconductor device in accordance with another embodiment of the present invention.

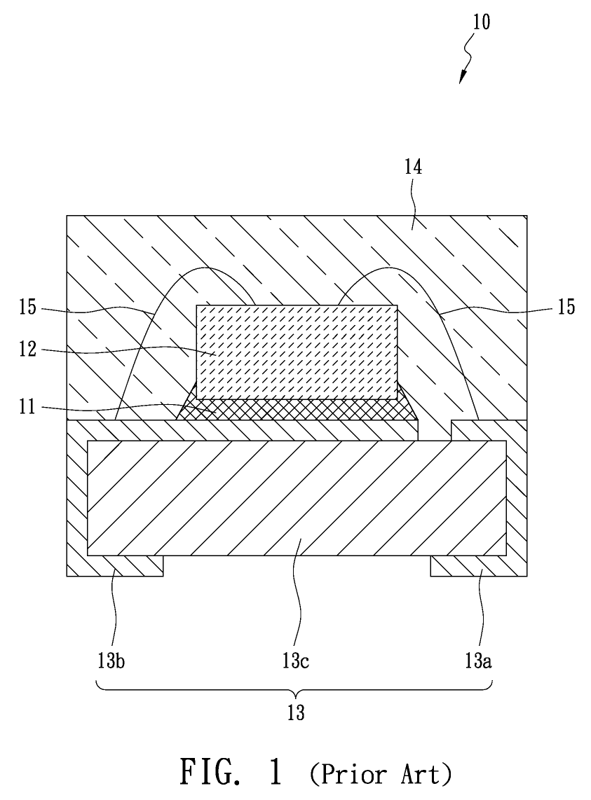

### DETAILED DESCRIPTION OF THE INVENTION

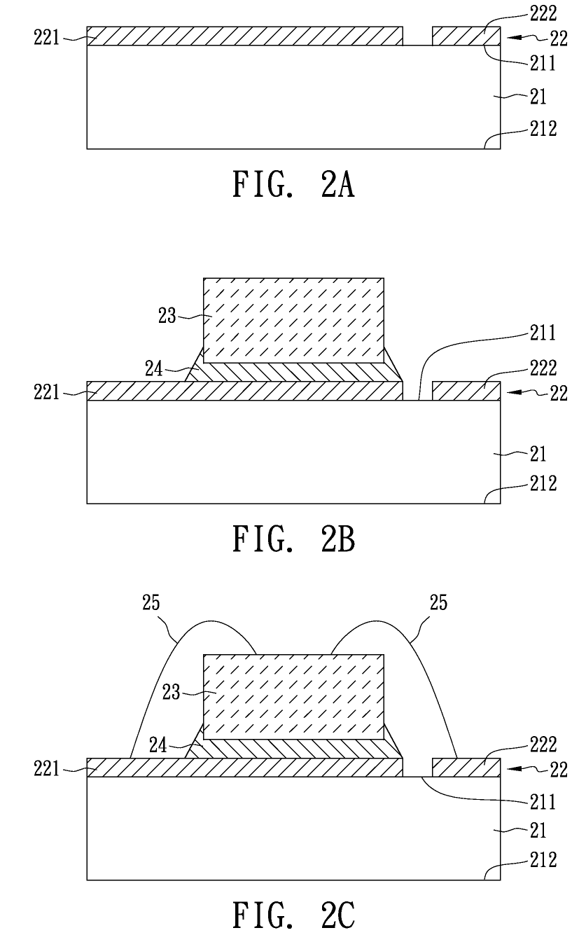

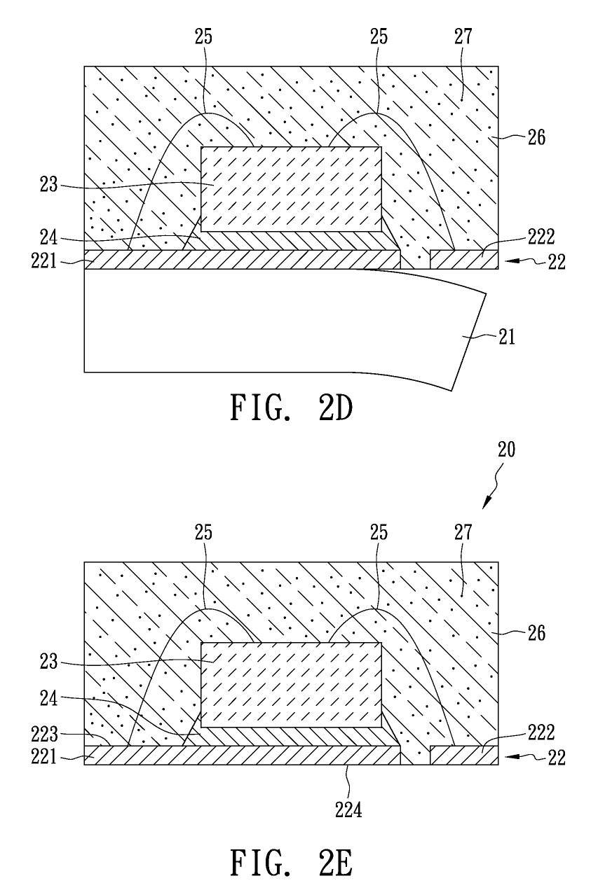

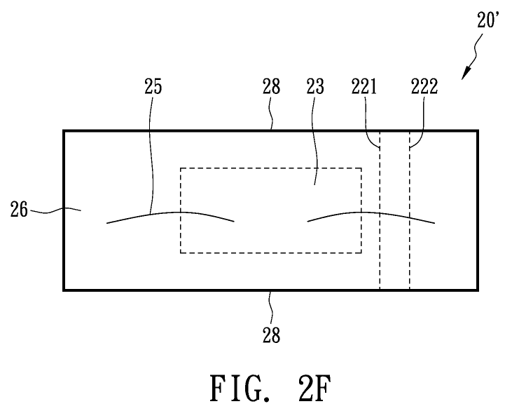

FIGS. 2A-2F are schematic illustrations showing the manufacturing steps of the package structure of a compound semiconductor device in accordance with the present invention. As shown in FIG. 2A, a temporary substrate 21 comprises a first surface 211 and a second surface 212. In this drawing, the first surface 211 is an upper surface and the second surface 212 is a lower surface. The temporary substrate 21 is made of a metallic material, a ceramic material and a polymer material. A conductive film 22 with a pattern is formed on the first surface 211 through printing, screening, electroform, chemical plating (or electroless plating) or sputtering. The material of the conductive film 22 is silver, nickel, copper, tin, aluminum or an alloy of the aforesaid metallic materials. Furthermore, indium tin oxide (ITO), indium zinc oxide (IZO), indium gallium oxide (IGO) and indium tungsten oxide (IWO) also are suitable for the material of the conductive film 22, and the film further comprises an N type electrode 221 and a P type electrode 222 or has a contact pattern with multiple isolated areas.

As shown in FIGS. 2B-2C, a chemical compound semiconductor die 23 is mounted on the N type electrode 221 through a die bonding adhesive 24, and then is electrically connected to the N type electrode 221 and P type electrode 222 through metal wires 25 by wire bonding. Furthermore, instead of the die bonding paste, the die 12 can be mounted on the N type electrode 221 by eutectic bonding. Subsequently, a transparent encapsulation material 26 such as epoxy resin and silicone is overlaid on the die 23, N type electrode 221, P type electrode 222 and metal wire 25. The transparent encapsulation material 26 is further mixed with fluorescent powders 27 so that a secondary light can be emitted from the excited fluorescent powders 27. The secondary light is mixed with a primary light emitted from the die 23 to form a white light or electromagnetic radiation waves with multiple wavelengths. The material of the mixed fluorescent powders 27 is YAG, TAG, silicate, or nitride-based fluorescent powders. The transparent encapsulation material 26 is overlaid on the die 23 by transfer-molding or injection molding.

After the transparent encapsulation material 26 is hardened, the substrate 21 is removed by bending, separating, etching, laser cutting or grinding. Therefore, a second surface 224 of the conductive film 22 appears on the encapsulation material 26. Accordingly, the package structure of the compound semiconductor device 20 is completed, as shown in FIG. 2E. The second surface 224 of the conductive film 22 is opposite to a first surface 223 of the conductive film 22, and the first surface 223 is still covered by the encapsulation material 26.

For directing and concentrating the light from the semiconductor die 23 to emit from the top surface of the encapsulation material 26, a reflection layer 28 can cover the sides of the encapsulation material 26, as shown in FIG. 2F. Light emitted from the die 23 of the compound semiconductor device 20′ is reflected by the reflection layer 28 and directed toward the upside of the circuit surface of the die 23 and out from the encapsulation material 26. The material of the reflection layer 28 can be an opaque adhesive including the material with a high reflection coefficient such as titanium dioxide.

Because the second surface 224 of N type electrode 221 and P type electrode 222 are not covered by the transparent encapsulation material 26, they can serve as outer contacts for surface mounting. Furthermore, the heat generated from the die 23 is directly transferred by the thin conductive film 22 with a superior conductive coefficient so that the heat dissipation efficiency of the package structure is improved. Compared with prior arts, the compound semiconductor device 20 does not need a printed circuit board for the whole package structure, and, therefore, the thickness of the package structure can be reduced to 0.2 mm-0.15 mm. In this embodiment, the die 23 can be an LED, a laser LED or a photocell.

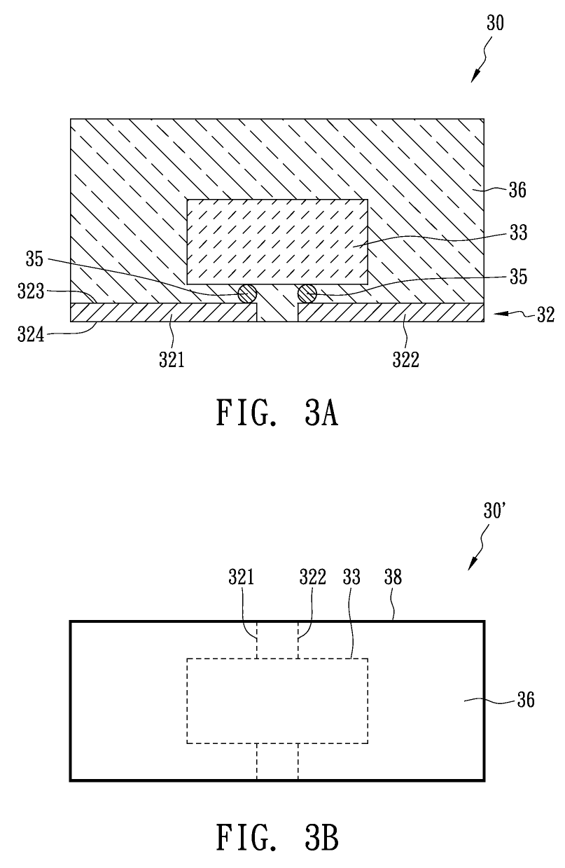

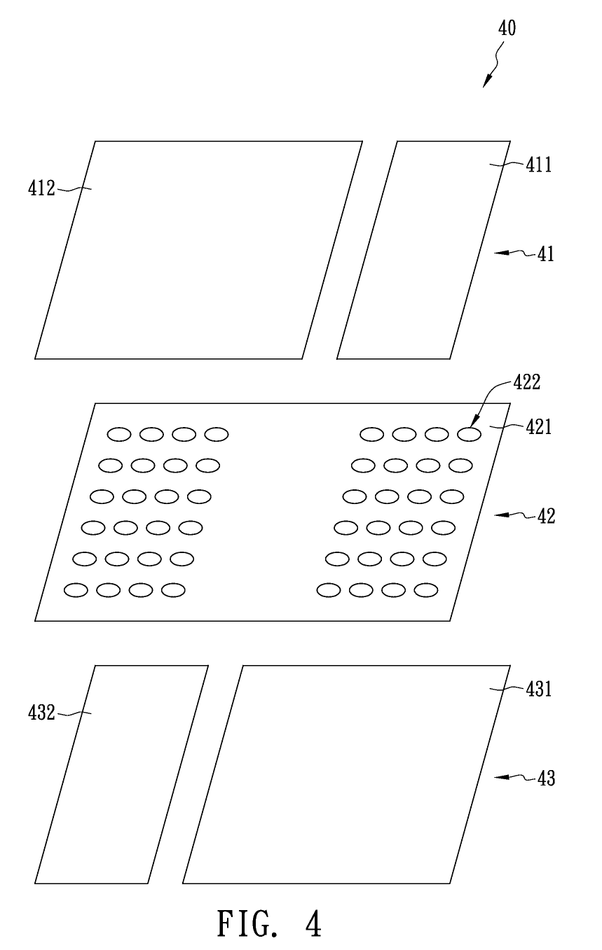

FIG. 3A is a cross-section view of the package structure of a compound semiconductor device in accordance with another embodiment of the present invention. The compound semiconductor device 30 comprises a conductive film 32 with a pattern, a die 33 and a transparent encapsulation material 36. The die 33 is mounted on a first surface 323 of the conductive film 32 through flip chip bonding, and is electrically connected to the N type electrode 321 and P type electrode 322 through a plurality of bumps 35. A transparent encapsulation material 36 is overlaid on a first surface 323 of the conductive film 32 and the die 33, and a second surface 324 of the conductive film 32 is not covered by the encapsulation material 36.

For directing and concentrating the light from the semiconductor die 33 to emit from the top surface of the encapsulation material 36, a reflection layer 38 can cover the sides of the encapsulation material 36, as shown in FIG. 3B. Light emitted from the die 33 of the compound semiconductor device 30′ is reflected by the reflection layer 38 and directed toward the upside of the circuit surface of the die 33 and out from the encapsulation material 36. In this embodiment, the die 33 can be an LED, a laser LED or a photocell.

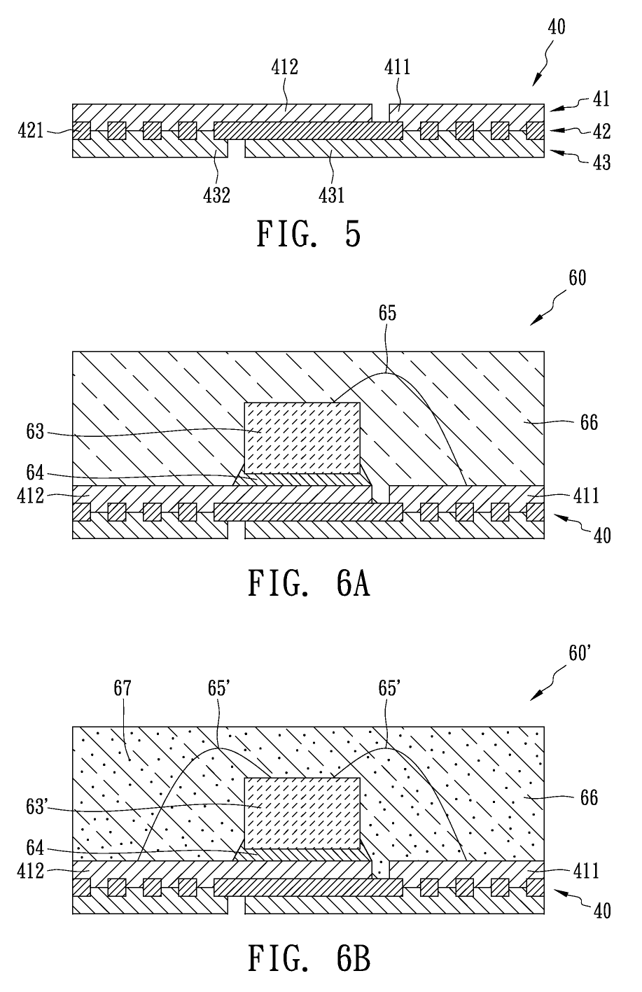

FIG. 4 is an exploded diagram showing each layer of a thin film substrate in accordance with the present invention, and FIG. 5 is a cross-sectional diagram of a thin film substrate in accordance with the present invention. The thin substrate 40 comprises an upper conductive film 41, an insulation layer 42 and a lower conductive film 43, and the N type electrode 412 of the upper conductive film 41 contacts the N type electrode 432 of the lower conductive film 43 through a plurality of openings 422 on the insulation layer 42, as shown in FIG. 5. Similarly, the P type electrode 411 of the upper conductive film 41 contacts the P type electrode 431 of the lower conductive film 43 through a plurality of openings 422 on the insulation layer 42. Because the thickness of the insulation layer 42 is around 0.01-0.1 mm, the upper conductive film 41 and the lower conductive film 43 easily contact each other through the openings 422. The insulation layer 42 is a thin film 421 made of polyimide, PV (polyvinyl), PC (polycarbonate), PVC (polyvinyl chloride), PMMA (polymethylmethacrylate) or acrylic. When polyimide is chosen for the thin film 421, it is formed on a plate through dispensation, dip or sol gel. Subsequently, the plurality of openings 42 with around 0.1 mm diameter are formed on the insulation film 421 through mechanical drilling, laser drilling or plasma etching. The upper conductive film 41 and the lower conductive film 43 are formed on the insulation film 421 through electroplating, printing or copper foil pressing. Furthermore, heat is easily transferred between the upper conductive film 41 and the lower conductive film 43 through the openings 422.

FIGS. 6A-6B are cross-sectional diagrams of the package structures of compound semiconductor devices in accordance with two further embodiments of the present invention. The compound semiconductor device 60 comprises a substrate 40, a die 63, a metal wire 65 and a transparent encapsulation material 66. The die 63 is mounted on the substrate 40 through a die bonding adhesive 64 or eutectic bonding, and its backside that is an N type substrate can be electrically connected to an N type electrode 412 through the die bonding adhesive 64. Furthermore, as shown in FIG. 6B, the die 63′ of the compound semiconductor device 60′ is formed on a non-semiconductor substrate such as a sapphire substrate. Therefore, two metal wires 65′ are necessary for electrically connecting the die 63′ to the N type electrode 412 and P type electrode 411. The transparent encapsulation material 66 is further mixed with fluorescent powders 67 so that a secondary light can be emitted from the excited fluorescent powders 67. The secondary light is mixed with a primary light emitted from the die 63′ to form a white light or electromagnetic radiation waves with multiple wavelengths. The material of the mixed fluorescent powders 67 is YAG, TAG, silicate, or nitride-based fluorescent powders. In this embodiment, the die 63 can be an LED, a laser LED or a photocell. The transparent encapsulation material 66 is overlaid on the die 63 by transfer-molding or injection molding.

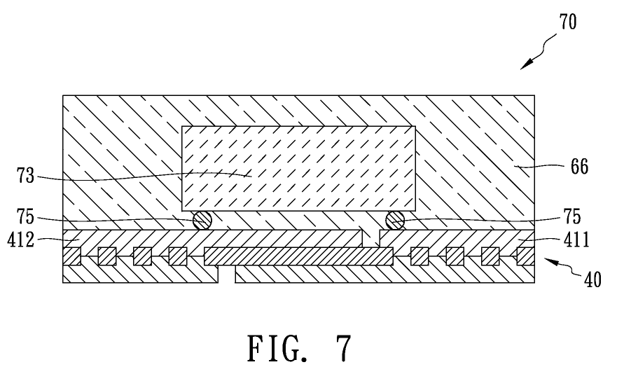

FIG. 7 is a cross-sectional diagram of the package structure of a compound semiconductor device in accordance with another embodiment of the present invention. The compound semiconductor device 70 comprises a substrate 40, a die 73 and a transparent encapsulation material 66. The die 73 is mounted on the substrate 40, and is electrically connected to the N type electrode 412 and P type electrode 411 respectively through a plurality of bumps 75. In this embodiment, the die 73 can be an LED, a laser LED or a photocell. Regarding the embodiments of FIGS. 6-7, a reflection layer is also used for increasing the brightness.

The above-described embodiments of the present invention are intended to be illustrative only. Those skilled in the art may devise numerous alternative embodiments without departing from the scope of the following claims.

What is claimed is:

1. A package structure of a compound semiconductor device, comprising:
a thin substrate including a first electrode and a second electrode;
a chemical compound semiconductor die on the thin substrate;
means for mounting the semiconductor die on the thin substrate; and
a transparent encapsulation material overlaying the semiconductor die.

2. The package structure of the compound semiconductor device of claim 1, wherein the thin substrate is a conductive film with a pattern or a composite substrate, and the composite substrate comprises a first conductive film with a first pattern, an insulation film having a plurality of holes and a second conductive film with a second pattern.

3. The package structure of a compound semiconductor device of claim 2, wherein the semiconductor die is an LED, a laser LED or a photocell.

4. The package structure of a compound semiconductor device of claim 3, wherein the means comprise wire bonding and flip chip bonding for mounting the semiconductor die on the thin substrate.

5. The package structure of a compound semiconductor device of claim 4, wherein the semiconductor die is mounted on the thin substrate through die bonding paste or eutectic bonding before the wire bonding.

6. The package structure of a compound semiconductor device of claim 2, further comprising a color conversion material mixed with the transparent encapsulation material, wherein the color conversion material is fluorescent powders.

7. The package structure of a compound semiconductor device of claim 6, wherein the transparent encapsulation material is epoxy resin or silicone.

8. The package structure of a compound semiconductor device of claim 1, further comprising a reflective layer around the transparent encapsulation material.

9. A package method of a compound semiconductor device, comprising the steps of:
providing a thin substrate including a first electrode and a second electrode;
mounting a semiconductor die on the thin film substrate whereby a positive electrode of the semiconductor die is connected to a first electrode and a negative electrode of the semiconductor die is connected to the second electrode; and
overlaying a transparent encapsulation material on the semiconductor die.

10. The package method of a compound semiconductor device of claim 9, wherein the thin substrate is a conductive film with a pattern or a composite substrate.

11. The package method of a compound semiconductor device of claim 10, wherein the conductive film with a pattern is a patterning conductive layer formed on a temporary substrate, and the temporary substrate is removed after the semiconductor die is overlaid with the transparent encapsulation material.

12. The package method of a compound semiconductor device of claim 11, wherein the conductive film is formed on the temporary substrate through printing, screen printing, electroforming, chemical plating or sputtering, and the temporary substrate is removed by bending, separating, etching, laser cutting or grinding.

13. The package method of a compound semiconductor device of claim 10, wherein the composite substrate comprises a first conductive film with a first pattern, an insulation film having a plurality of holes and a second conductive film with a second pattern.

14. The package method of a compound semiconductor device of claim 13, wherein a manufacturing method of the composite substrate comprises the steps of:
providing an insulation film having the plurality of holes; and
fixing the first conductive film and the second conductive film respectively on two opposite surfaces of the insulation film with the plurality of holes whereby the first conductive film with a first pattern and the second conductive film with a second pattern are electrically connected to each other through the plurality of holes.

15. The package method of a compound semiconductor device of claim 14, wherein the semiconductor die is a light emitting diode, a laser diode or a photo sensor.

16. The package method of a compound semiconductor device of claim 9, wherein the step of mounting a semiconductor die on the thin film substrate further comprises a sub-step of electrically connecting the semiconductor die to the thin substrate through wire bonding or flip chip bonding.

17. The package method of a compound semiconductor device of claim 16, wherein the semiconductor die is mounted on the thin substrate through die bonding paste or eutectic bonding before the wire bonding.

18. The package method of a compound semiconductor device of claim 17, further comprising a color conversion material mixed with the transparent encapsulation material, wherein the color conversion material is fluorescent powders.

19. The package method of a compound semiconductor device of claim 17, wherein the transparent encapsulation material is epoxy resin or silicone.

20. The package method of a compound semiconductor device of claim 17, further comprising a step of attaching a reflective layer around the transparent encapsulation material.

21. A package structure of a compound semiconductor device, comprising:
a conductive film with a pattern including a first surface and a second surface, wherein the first surface is opposite to the second surface;
a die mounted on the first surface of the conductive film; and
a transparent encapsulation material overlaid on the first surface of the conductive film and the die.

22. The package structure of a compound semiconductor device of claim 21, further comprising at least one metal wire electrically connecting the die and the conductive film.

23. The package structure of a compound semiconductor device of claim 21, further comprising at least one bump electrically connecting the die and the conductive film.

24. The package structure of a compound semiconductor device of claim 21, wherein the material of the conductive film is silver, nickel, copper, tin, aluminum or the alloy of the aforesaid metals.

25. The package structure of a compound semiconductor device of claim 21, wherein the material of the conductive film is indium tin oxide (ITO), indium zinc oxide (IZO), indium gallium oxide (IGO) and indium tungsten oxide (IWO).

26. The package structure of a compound semiconductor device of claim 21, wherein the conductive film comprises an N type electrode and a P type electrode.

27. The package structure of a compound semiconductor device of claim 21, wherein the transparent encapsulation material is further mixed with fluorescent powders.

28. The package structure of a compound semiconductor device of claim 21, wherein the die is mounted on the first surface of the conductive film through die bonding paste or eutectic bonding.

29. The package structure of a compound semiconductor device of claim 21, further comprising a reflective layer around the transparent encapsulation material.

30. A package method of a compound semiconductor device, comprising the steps of:
providing a temporary substrate;
forming a conductive film with a pattern on the temporary substrate, wherein the conductive film has a first surface and a second surface opposite the first surface;
mounting a die to the first surface of the conductive film;
overlaying a transparent encapsulation material on the first surface of the conductive film and the die; and
removing the temporary substrate.

31. The package method of a compound semiconductor device of claim 30, further comprising a step of electrically connecting the die to the conductive film through a plurality of metallic wires.

32. The package method of a compound semiconductor device of claim 31, further comprising a step of electrically connecting the die to the conductive film through a plurality of bumps.

33. The package method of a compound semiconductor device of claim 30, wherein the conductive film is formed on the temporary substrate through printing, screen printing, electroforming, chemical plating or sputtering.

34. The package method of a compound semiconductor device of claim 30, wherein the temporary substrate is removed by bending, separating, etching, laser cutting or grinding.

35. The package method of a compound semiconductor device of claim 30, wherein the material of the conductive film is silver, nickel, copper, tin, aluminum or the alloy of the aforesaid metals.

36. The package method of a compound semiconductor device of claim 30, wherein the material of the conductive film is indium tin oxide (ITO), indium zinc oxide (IZO), indium gallium oxide (IGO) or indium tungsten oxide (IWO).

37. The package method of a compound semiconductor device of claim 30, further comprising a step of attaching a reflective layer around the transparent encapsulation material.

38. A package structure of a compound semiconductor device, comprising:
a thin film substrate comprising an upper conductive film, an insulation film including a plurality of openings, and a lower conductive film, wherein the insulation film is sandwiched between the upper conductive film and lower conductive film;
a die mounted on the upper conductive film; and
an encapsulation material overlaid on the upper conductive film and the die.

39. The package structure of a compound semiconductor device of claim 38, wherein each of the upper conductive film and lower conductive film comprises an N type electrode and a P type electrode, the N type electrodes of the upper conductive film and the lower conductive film contact each other through the plurality of openings, and the P type electrodes of the upper conductive film and lower conductive film contact each other through the plurality of openings.

40. The package structure of a compound semiconductor device of claim 38, wherein the thickness of the insulation layer is between 0.01 mm and 0.1 mm.

41. The package structure of a compound semiconductor device of claim 38, wherein the material of the insulation layer is polyimide, PV (polyvinyl), PC (polycarbonate), PVC (polyvinyl chloride), PMMA (polymethylmethacrylate) or acrylic.

42. The package structure of a compound semiconductor device of claim 38, further comprising at least one metal wire electrically connecting the die and the conductive film.

43. The package structure of a compound semiconductor device of claim 38, further comprising at least one bump electrically connecting the die and the conductive film.

44. The package structure of a compound semiconductor device of claim 38, further comprising a reflective layer around the transparent encapsulation material.

45. A package method of a compound semiconductor device, comprising the steps of:
providing an insulation film including a plurality of openings;
forming an upper conductive film and a lower conductive film respectively on two surfaces of the insulation film, wherein the upper conductive film and the lower conductive film contact each other through the plurality of openings;
mounting a die on the upper conductive film; and
overlaying a transparent encapsulation material on the upper conductive film and the die.

46. The package method of a compound semiconductor device of claim 45, further comprising the steps of:
forming the insulation film on a plate; and
forming the plurality of openings on the insulation film.

47. The package method of a compound semiconductor device of claim 46, wherein the insulation film is formed on the plate through dispensation, dip or sol gel.

48. The package method of a compound semiconductor device of claim 46, wherein the plurality of openings are formed on the insulation film through mechanical drilling, laser drilling or plasma etching.

49. The package method of a compound semiconductor device of claim 46, wherein the upper conductive film and the lower conductive film are formed on the insulation film through electroplating, printing or copper foil pressing.

50. The package method of a compound semiconductor device of claim 45, wherein each of the upper conductive film and lower conductive film comprises an N type electrode and a P type electrode, the N type electrodes of the upper conductive film and the lower conductive film contact each other through the plurality of openings, and the P type electrodes of the upper conductive film and lower conductive film contact each other through the plurality of openings.

51. The package method of a compound semiconductor device of claim 45, further comprising a step of electrically connecting the die to the conductive film through a plurality of metallic wires.

52. The package method of a compound semiconductor device of claim 45, further comprising a step of electrically connecting the die to the conductive film through a plurality of bumps.

53. The package method of a compound semiconductor device of claim 45, further comprising a step of attaching a reflective layer around the transparent encapsulation material.

54. A manufacturing method of a thin film substrate used in a light emitting diode, comprising the steps of:
providing a temporary substrate;
forming a conductive film with a pattern on the temporary substrate, wherein the conductive film comprises a first surface and a second surface opposite to the first surface; and
removing the temporary substrate after a package of a light emitting diode is completed.

55. A manufacturing method of a thin film substrate used in a light emitting diode, comprising the steps of:
providing an insulation film including a plurality of openings; and
forming a first conductive film with a first pattern and a second conductive film with a second pattern respectively on two opposite surfaces of the insulation film, whereby the first conductive film and the second conductive film contact each other through the plurality of openings.
